(19) United States
(12) Patent Application Publication
(10) Pub. No.: US 2023/0112690 A1
(43) Pub. Date: Apr. 13, 2023

(54) DRIVER CIRCUIT WITH A SIGNAL OUTPUT

(71) Applicant: Lumentum Operations LLC, San Jose, CA (US)

(72) Inventors: Mikhail DOLGANOV, Gilroy, CA (US); Lijun ZHU, Pleasanton, CA (US); Hao HUANG, San Jose, CA (US)

(21) Appl. No.: 17/643,322

(22) Filed: Dec. 8, 2021

Related U.S. Application Data
(60) Provisional application No. 63/262,298, filed on Oct. 8, 2021.

(51) Int. Cl. G01S 7/4865; G01S 17/10; G01S 7/484

(52) U.S. Cl. CPC G01S 7/4865; G01S 7/484; G01S 17/10

(57) ABSTRACT

A driver circuit may include an inductive element and a first circuit path connected to the inductive element, the first circuit path including an optical emitter and a capacitive element in series with the optical emitter. The driver circuit may include a second circuit path connected to the inductive element, the second circuit path including a voltage divider element to produce an output signal and a signal output to provide the output signal to a time-to-digital converter. The driver circuit may include a switch having an open state and a closed state. The switch in the closed state may cause current to charge the inductive element. The switch transitioning from the closed state to the open state may cause the inductive element to discharge current to provide an electrical pulse through the first circuit path to the optical emitter and through the second circuit path to the signal output.

### CROSS-REFERENCE TO RELATED APPLICATION

This Patent Application claims priority to U.S. Provisional Pat. Application No. 63/262,298, filed on Oct. 08, 2021, and entitled “SHORT PULSE LASER DRIVER WITH FEEDBACK SIGNAL.” The disclosure of the prior Application is considered part of and is incorporated by reference into this Patent Application.

### TECHNICAL FIELD

The present disclosure relates generally to lasers and to a driver circuit with a signal output.

### BACKGROUND

Light detection and ranging (LIDAR) systems, such as time-of-flight (ToF)-based measurement systems, emit optical pulses, detect reflected optical pulses, and determine distances to objects by measuring delays between the emitted optical pulses and the reflected optical pulses.

### SUMMARY

In some implementations, a driver circuit includes an inductive element; a first circuit path connected to the inductive element, where the first circuit path includes an optical emitter and a capacitive element in series with the optical emitter; a second circuit path connected to the inductive element, where the second circuit path includes a voltage divider element to produce an output signal and a signal output configured to provide the output signal to a time-to-digital converter; and a switch having an open state and a closed state, where the switch in the closed state is to cause current to charge the inductive element, and where the switch transitioning from the closed state to the open state is to cause the inductive element to discharge current to provide an electrical pulse through the first circuit path to the optical emitter and through the second circuit path to the signal output.

In some implementations, an optical source includes a vertical cavity surface emitting laser (VCSEL); an inductive element; a first circuit path connected to the inductive element, where the first circuit path includes the VCSEL; a second circuit path connected to the inductive element, where the second circuit path includes a signal output; and a switch having an open state and a closed state, where the switch in the closed state is to cause current to charge the inductive element, and where the switch transitioning from the closed state to the open state is to cause the inductive element to discharge current to provide an electrical pulse through the first circuit path to the VCSEL and through the second circuit path to the signal output.

In some implementations, a light detection and ranging (LIDAR) system includes a time-to-digital converter and a driver circuit including: an inductive element; a first circuit path connected to the inductive element, where the first circuit path includes an optical emitter; a second circuit path connected to the inductive element, where the second circuit path includes a signal output configured to provide an output signal to the time-to-digital converter; and a switch having an open state and a closed state, where the switch in the closed state is to cause current to charge the inductive element, and where the switch transitioning from the closed state to the open state is to cause the inductive element to discharge current to provide an electrical pulse through the first circuit path to the optical emitter and through the second circuit path to the signal output.

### BRIEF DESCRIPTION OF THE DRAWINGS

FIG. 1 is a diagram of an example light detection and ranging (LIDAR) system described herein.

FIG. 2 is a diagram of an example driver circuit described herein.

FIG. 3 is a diagram of an example driver circuit described herein.

FIG. 4 is a diagram of an example driver circuit described herein.

FIG. 5 is a diagram of an example driver circuit described herein.

FIG. 6 is a diagram of example graphs plotting electrical signals associated with an example driver circuit described herein.

### DETAILED DESCRIPTION

The following detailed description of example implementations refers to the accompanying drawings. The same reference numbers in different drawings may identify the same or similar elements.

A controller of a light detection and ranging (LIDAR) system may provide a laser trigger pulse to a laser driver to cause a laser fire event (e.g., an optical pulse) at a laser of the LIDAR system. In the LIDAR system, highly accurate distance measurements may be achieved if the laser trigger pulse has a short rise time as well as if a start signal (e.g., a time-to-digital converter (TDC) start signal) from the laser fire event to a TDC of the LIDAR system has a short rise time. In addition, the start signal needs to be very stable over time and temperature to facilitate accurate measurements. However, a signal from the controller’s laser trigger pulse may experience propagation delay, from the controller to the laser driver, that may vary with temperature (e.g., due to temperature-dependent components in the driver signal chain from the controller to the laser) and cause errors in distance measurement.

In some cases, the start signal may be obtained using an optical signal pickup with a detector placed near the laser. However, here, the start signal may be degraded and have a longer rise time due to a limited bandwidth of the detector. Moreover, the additional circuitry for the optical pickup receiver increases the complexity and size of the LIDAR system.

Some implementations described herein provide a driver circuit capable of producing a stable, temperature-independent electrical start signal for use at a TDC of a LIDAR system. The driver circuit may generate a very short electrical pulse giving the start signal a fast rise time (e.g., as short as 40 picoseconds), thereby facilitating highly accurate measurement by the LIDAR system. In some implementations, the start signal may be derived from a current that provides the electrical pulse to an optical emitter (e.g., a laser) of the driver circuit. For example, the driver circuit may include an inductive element, a first circuit path, that includes the optical emitter, connected to the inductive element, and a second circuit path, that includes a signal output for the start signal, connected to the inductive element. Continuing with the example, the inductive element may be configured to discharge current to provide the electrical pulse through the first circuit path to the optical emitter and through the second circuit path to the signal output. In this way, the start signal enables measurement by the LIDAR system with improved accuracy.

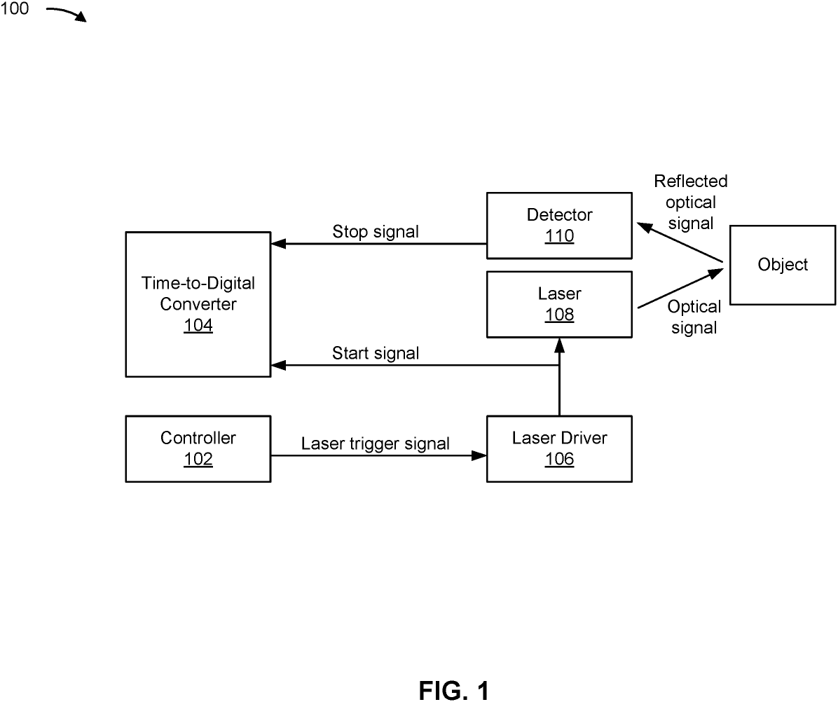

FIG. 1 is a diagram of an example LIDAR system 100 described herein. The LIDAR system 100 may include a controller 102, a TDC 104, a laser driver 106, a laser 108 (e.g., a vertical cavity surface emitting laser (VCSEL)), and a detector 110. As shown, the controller 102 may be configured to provide a laser trigger signal to the laser driver 106. The laser trigger signal may cause the laser driver 106 to provide an electrical pulse to the laser 108, thereby causing emission of an optical signal at the laser 108. Moreover, the laser driver 106 may provide a start signal (e.g., a feedback signal) to the TDC 104. As further shown, the detector 110 may detect a reflection of the optical signal from an object. Based on detecting the reflection, the detector 110 may provide a stop signal to the TDC 104. The TDC 104 may determine a time interval between the start signal and the stop signal, which may be used to determine a distance of the object from the LIDAR system.

As indicated above, FIG. 1 is provided as an example. Other examples may differ from what is described with regard to FIG. 1.

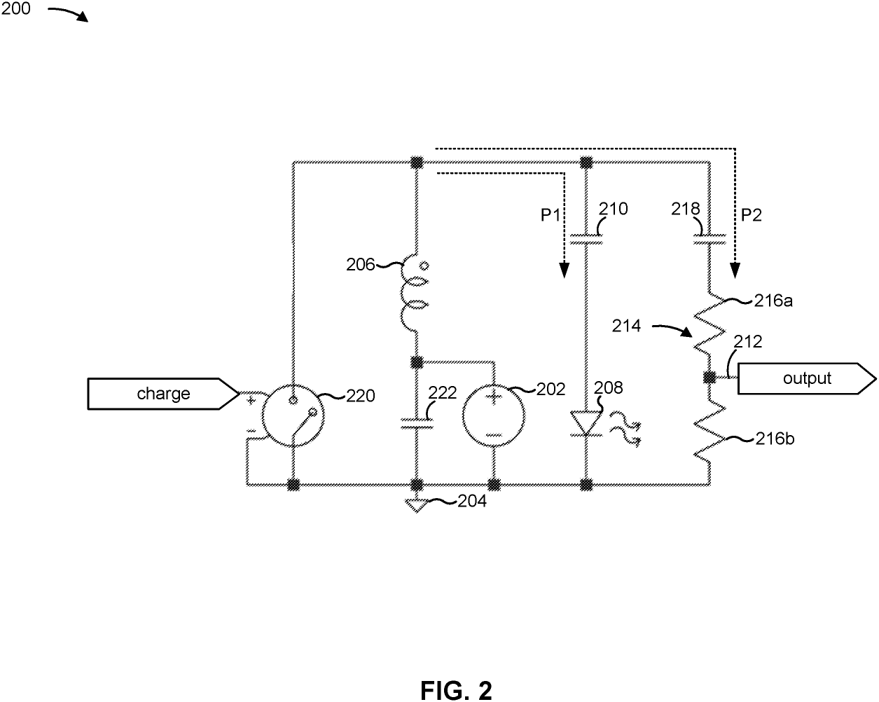

FIG. 2 is a diagram of an example driver circuit 200 described herein. In some implementations, the LIDAR system 100 may include the driver circuit 200. For example, the laser driver 106 of the LIDAR system 100 may include the driver circuit 200.

The driver circuit 200 may include a set of electronic components interconnected by current-carrying conductors (e.g., traces). The driver circuit 200 may include a source 202. The source 202 may provide an electrical input of the driver circuit 200. For example, the source 202 may provide current to the driver circuit 200. The source 202 may be a direct current (DC) voltage source, a DC current source with a resistive load, or the like. In some implementations, an input supply voltage at the source 202 may be in a range from 2 volts (V) to 50 V. The driver circuit 200 may include a ground 204.

The driver circuit 200 may include an inductive element 206. The inductive element 206 may provide an inductive current source of the driver circuit 200. The inductive element 206 may include one or more inductor components (e.g., surface mount inductors) and/or one or more sections of a trace (e.g., a printed circuit board (PCB) trace) of the driver circuit 200. The inductive element 206 may have an inductance in range from 500 picohenries to 10 nanohenries.

The driver circuit 200 may include a first circuit path (shown as P1) connected to the inductive element 206. The first circuit path may include an optical emitter 208. The optical emitter 208 may include a light-emitting diode (LED), a laser diode, a semiconductor laser diode, a VCSEL, and/or an edge-emitting emitter (e.g., an edge-emitting laser), among other examples. For example, the optical emitter 208 may include a VCSEL that includes one active layer or multiple active layers (e.g., 2, 3, 4, 5, 6, or more active layers), with a tunnel junction between consecutive active layers, for higher peak optical power and higher efficiency. An active layer may include a layer that confines electrons and defines an emission wavelength of the optical emitter 208. For example, an active layer may be a quantum well. The optical emitter 208 may include an array of VCSELs.

In some implementations, the first circuit path may include a capacitive element 210 connected to the optical emitter 208 (e.g., to decouple the optical emitter 208 from the source 202). The capacitive element 210 may include a capacitor. The capacitive element 210 may provide capacitive coupling (e.g., alternating current (AC) coupling) of the first circuit path with the inductive element 206 (e.g., the inductive element 206 is capacitively coupled to the optical emitter 208). The capacitive element 210 may have a capacitance in a range from 500 picofarads to 20 nanofarads.

The driver circuit 200 may include a second circuit path (shown as P2) connected to the inductive element 206. The second circuit path may include a signal output 212. The signal output 212 may be configured to output an output signal (e.g., a start signal) to a TDC (e.g., TDC 104). The signal output 212 of the second circuit path may be in parallel with the optical emitter 208 of the first circuit path.

In some implementations, the second circuit path may include a voltage divider element 214 (e.g., a resistive voltage divider) configured to produce a lower level output signal. The voltage divider element 214 may include a first resistive element 216a (e.g., a resistor) and a second resistive element 216b (e.g., a resistor). A ratio of a resistance R1 of the first resistive element 216a and a resistance R2 of the second resistive element 216b may be selected to achieve a particular voltage of the output signal that is suitable for the TDC. In some implementations, the resistance R2 may be selected to match an impedance of a transmission line (e.g., a trace) from the signal output 212 to the TDC. Moreover, an impedance of the first resistive element 216a and the second resistive element 216b may be minimized to facilitate faster response time. The signal output 212 may be located between the first resistive element 216a and the second resistive element 216b.

In addition to, or as an alternative to, the voltage divider element 214, the second circuit path may include a transimpedance amplifier (not shown). The transimpedance amplifier may be configured to produce the output signal that is output at the signal output 212. In some implementations, the second circuit path may include a capacitive element 218. The capacitive element 218 may provide capacitive coupling (e.g., AC coupling) of the second circuit path with the inductive element 206 (e.g., the inductive element 206 is capacitively coupled to the signal output 212). Use of the capacitive element 218 may reduce an idle power consumption of the driver circuit 200. The capacitive element 218 may have a capacitance in a range from 1 picofarad to 10 picofarads (e.g., to minimize an amount of current that is bypassed to the second circuit path). In some implementations, a ratio of the capacitance of the capacitive element 210 to the capacitance of the capacitive element 218 may be about (e.g., ±10%) 100:1.

The driver circuit 200 may include a switch 220. The switch 220 may be connected to the inductive element 206. For example, a circuit path of the driver circuit 200 may include the inductive element 206 and the switch 220. Moreover, the switch 220 may control charging of the inductive element 206.

The switch 220 may have a closed state (e.g., an on state) where, when the switch 220 is in the closed state, current may flow through the switch 220. Additionally, the switch 220 may have an open state (e.g., an off state), where, when the switch 220 is in the open state, current may not flow through the switch 220. The switch 220 may transition to the closed state in response to a “charge” signal. For example, a controller of a LIDAR system (e.g., controller 102 of LIDAR system 100) may provide the “charge” signal to the switch 220.

Thus, in the closed state, the switch 220 may cause current to charge the inductive element 206 (e.g., by completing a circuit path that includes the source 202, the inductive element 206, and the switch 220). That is, when the switch 220 is in the closed state, current may flow through the switch 220 and charge the inductive element 206. In some implementations, when the switch 220 is in the closed state, current may flow through the switch 220 and charge the inductive element 206 during a time interval (e.g., a charging time). The time interval may be in a range from 1 nanosecond (ns) to 50 ns, 1 ns to 20 ns, 1 ns to 10 ns, or the like. When transitioning from the closed state to the open state, the switch 220 may cause the inductive element 206 to discharge current. That is, when the switch 220 is in the open state, current may not flow through the switch 220, and current discharges from the inductive element 206. The inductive element 206 may discharge current to provide an electrical pulse through the first circuit path to the optical emitter 208 and through the second circuit path to the signal output 212.

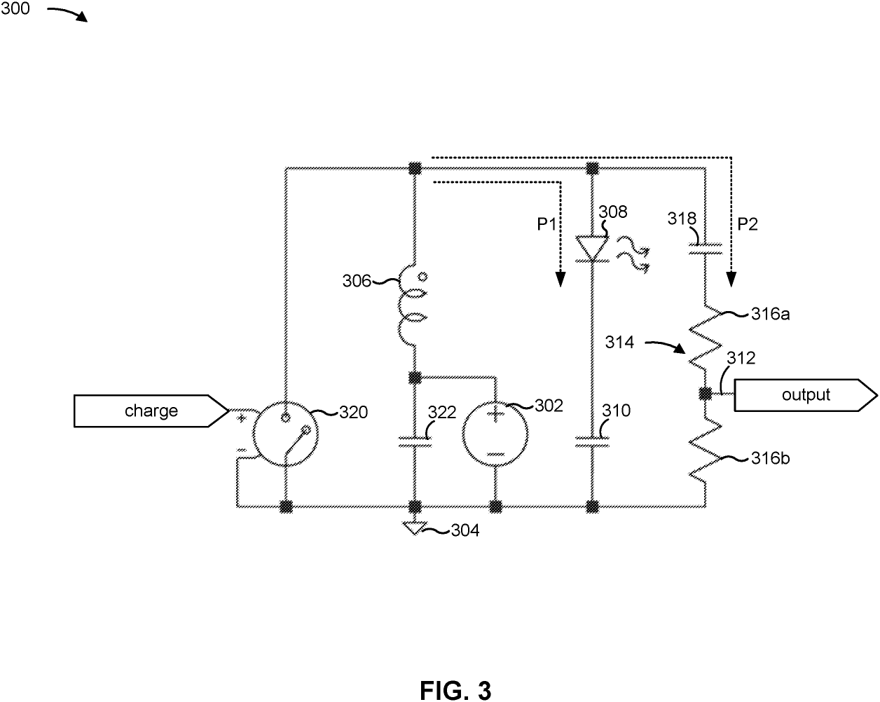

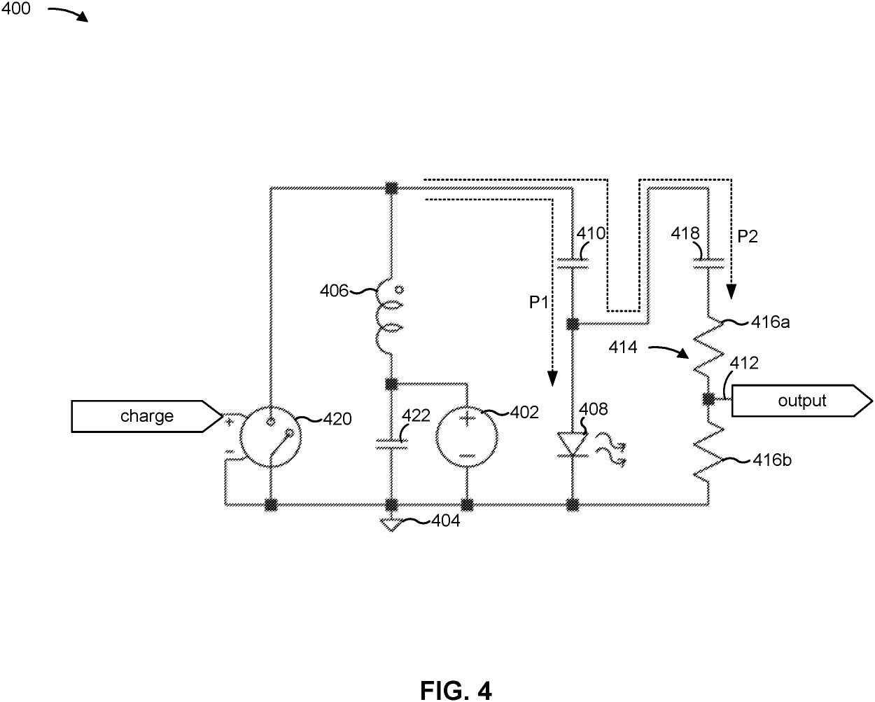

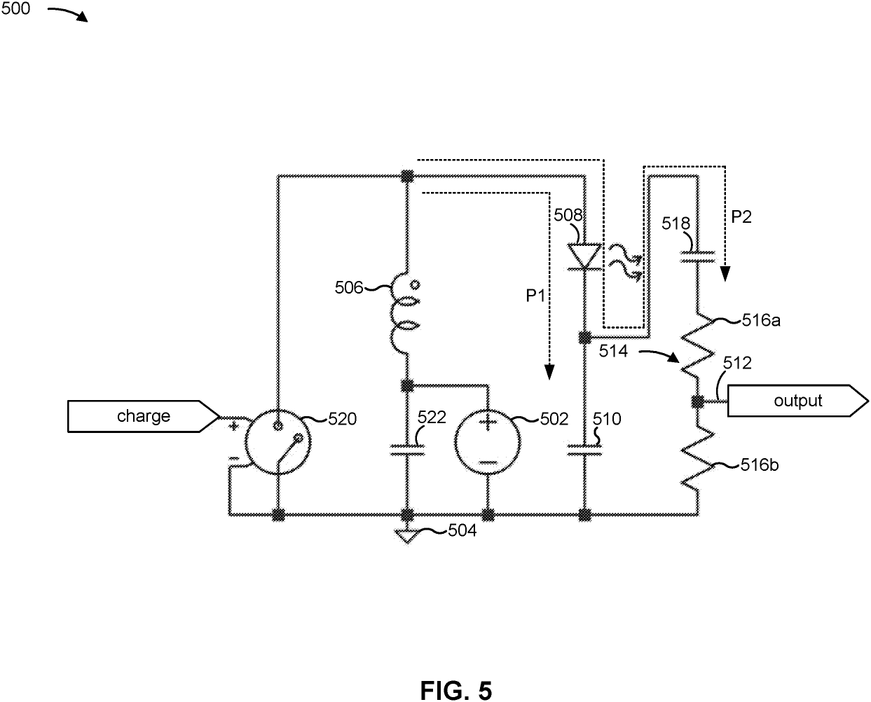

In some implementations, as shown in FIG. 2, a cathode of the optical emitter 208 may be connected to the ground 204, and the output signal that is output at the signal output 212 is from a drain of the switch 220 (e.g., the capacitively coupled voltage divider element 214 may be connected to the drain of the switch 220). That is, the capacitive element 210 is between the inductive element 206 and the optical emitter 208 in the first circuit path, as shown. Connection of the cathode of the optical emitter 208 to the ground 204 may provide improved thermal dissipation due to the enhanced heatsinking capabilities of the ground plane. In some implementations, as described in connection with FIG. 3, an anode of the optical emitter 208 and the signal output 212 may be connected to the drain of the switch 220. In some implementations, as described in connection with FIG. 4, the cathode of the optical emitter 208 may be grounded, and the output signal that is output at the signal output 212 is from the anode of the optical emitter 208. In some implementations, as described in connection with FIG. 5, an anode of the optical emitter 208 may be connected to the drain of the switch 220, and the output signal that is output at the signal output 212 is from the cathode of the optical emitter 208.

The switch 220 may be a field effect transistor (FET). For example, the FET may be a silicon FET, a gallium nitride (GaN) FET, a complementary metal-oxide-semiconductor (CMOS) FET, or the like. In some implementations, the driver circuit 200 may include a high current gate driver for driving a gate of the switch 220. Alternatively, the high current gate driver may be omitted when a long charging time interval (e.g., greater than 4 ns) is used for the inductive element 206.

In some implementations, the driver circuit 200 may include a capacitive element 222 connected to (e.g., in parallel with) the source 202. The capacitive element 222 may be configured to provide a supply current to the inductive element 206. The capacitive element 222, when located near the inductive element 206, may minimize parasitic inductances of a trace between the inductive element 206 and the capacitive element 222.

In an example operation of the driver circuit 200, the switch 220 may transition from the open state to the closed state (e.g., in response to a “charge” signal) to cause current (e.g., from the source 202) to charge the inductive element 206. Continuing with the example, the switch 220 may transition from the closed state to the open state to cause the inductive element 206 to discharge current through the first circuit path and the second circuit path. The discharged current may provide an electrical pulse to the optical emitter 208, and the optical emitter 208 may emit an optical pulse (e.g., for a duration of 1 ns or less) in response to the electrical pulse. In addition, the discharged current may provide the electrical pulse (e.g., the output signal) to the TDC via the signal output 212. In this way, the driver circuit 200 provides a start signal for the TDC that is stable and has a fast rise time, thereby facilitating highly accurate LIDAR measurement.

The driver circuit 200 is a high-speed driver circuit capable of generating narrow electrical and/or optical pulses having a width (in a time domain) less than 2 ns or less than 1 ns. For example, the driver circuit 200 may generate electrical and/or optical pulses having a width in a range from 100 picoseconds (ps) to 2 ns. The pulse width may be a function of an inductance of the inductive element 206 and/or a capacitance of the capacitive element 210. Moreover, by positioning elements of the first circuit path as close together as possible, and by positioning elements of the second circuit path as close together as possible, the pulse width may be minimized by minimizing parasitic trace inductances. In some implementations, the driver circuit 200 may generate an electrical and/or optical pulse that is a Gaussian pulse. Moreover, the driver circuit 200 may generate a high peak current for an electrical pulse, thereby producing an optical pulse with high peak power. For example, the peak current may be in a range from 1 amp (A) to 100 A. The peak current may be a function of a charging time of the inductive element 206 (e.g., a pulse width of the “charge” signal), an input power supply voltage at the source 202, and/or a capacitance of the capacitive element 210.

As indicated above, FIG. 2 is provided as an example. Other examples may differ from what is described with regard to FIG. 2.

FIG. 3 is a diagram of an example driver circuit 300 described herein. In some implementations, the LIDAR system 100 may include the driver circuit 300. For example, the laser driver 106 of the LIDAR system 100 may include the driver circuit 300.

The driver circuit 300 may include a source 302, a ground 304, and/or an inductive element 306, in a similar manner as described in connection with FIG. 2. The driver circuit 300 may include a first circuit path (shown as P1) connected to the inductive element 306 that includes an optical emitter 308 and/or a capacitive element 310, in a similar manner as described in connection with FIG. 2. The driver circuit 300 may include a second circuit path (shown as P2) connected to the inductive element 306 that includes a signal output 312, a voltage divider element 314 (e.g., including a first resistive element 316a and a second resistive element 316b), and/or a capacitive element 318, in a similar manner as described in connection with FIG. 2. The driver circuit 300 may include a switch 320 and/or a capacitive element 322, in a similar manner as described in connection with FIG. 2. As shown in FIG. 3, an anode of the optical emitter 308 and the signal output 312 may be connected to a drain of the switch 320 (e.g., the capacitively coupled voltage divider element 314 may be connected to the drain of the switch 320). For example, the optical emitter 308 may be between the inductive element 306 and the capacitive element 310 in the first circuit path.

As indicated above, FIG. 3 is provided as an example. Other examples may differ from what is described with regard to FIG. 3.

FIG. 4 is a diagram of an example driver circuit 400 described herein. In some implementations, the LIDAR system 100 may include the driver circuit 400. For example, the laser driver 106 of the LIDAR system 100 may include the driver circuit 400.

The driver circuit 400 may include a source 402, a ground 404, and/or an inductive element 406, in a similar manner as described in connection with FIG. 2. The driver circuit 400 may include a first circuit path (shown as P1) connected to the inductive element 406 that includes an optical emitter 408 and/or a capacitive element 410, in a similar manner as described in connection with FIG. 2. The driver circuit 400 may include a second circuit path (shown as P2) connected to the inductive element 406 that includes a signal output 412, a voltage divider element 414 (e.g., including a first resistive element 416a and a second resistive element 416b), and/or a capacitive element 418, in a similar manner as described in connection with FIG. 2. The driver circuit 400 may include a switch 420 and/or a capacitive element 422, in a similar manner as described in connection with FIG. 2.

As shown in FIG. 4, the capacitive element 410 may be in the first circuit path and the second circuit path. For example, the second circuit path may branch from the first circuit path between the capacitive element 410 and the optical emitter 408. Here, a cathode of the optical emitter 408 may be connected to the ground 404, and the capacitively coupled voltage divider element 414 may be connected to an anode of the optical emitter 408.

As indicated above, FIG. 4 is provided as an example. Other examples may differ from what is described with regard to FIG. 4.

FIG. 5 is a diagram of an example driver circuit 500 described herein. In some implementations, the LIDAR system 100 may include the driver circuit 500. For example, the laser driver 106 of the LIDAR system 100 may include the driver circuit 500.

The driver circuit 500 may include a source 502, a ground 504, and/or an inductive element 506, in a similar manner as described in connection with FIG. 2. The driver circuit 500 may include a first circuit path (shown as P1) connected to the inductive element 506 that includes an optical emitter 508 and/or a capacitive element 510, in a similar manner as described in connection with FIG. 2. The driver circuit 500 may include a second circuit path (shown as P2) connected to the inductive element 506 that includes a signal output 512, a voltage divider element 514 (e.g., including a first resistive element 516a and a second resistive element 516b), and/or a capacitive element 518, in a similar manner as described in connection with FIG. 2. The driver circuit 500 may include a switch 520 and/or a capacitive element 522, in a similar manner as described in connection with FIG. 2.

As shown in FIG. 5, the optical emitter 508 may be in the first circuit path and the second circuit path. For example, the second circuit path may branch from the first circuit path between optical emitter 508 and the capacitive element 510. Here, an anode of the optical emitter 508 may be connected to a drain of the switch 520, and the capacitively coupled voltage divider element 514 may be connected to a cathode of the optical emitter 408. In this way, current for an output signal at the signal output 512 is not wasted as the current is a portion of a main current for the optical emitter 508. Moreover, the output signal of the driver circuit 500 may be cleaner with less ringing and have a fast rise time.

As indicated above, FIG. 5 is provided as an example. Other examples may differ from what is described with regard to FIG. 5.

In some implementations, an optical source may include the driver circuit 200 or a portion thereof, the driver circuit 300 or a portion thereof, the driver circuit 400 or a portion thereof, and/or the driver circuit 500 or a portion thereof. In some implementations, an optical system may include the driver circuit 200 or a portion thereof, the driver circuit 300 or a portion thereof, the driver circuit 400 or a portion thereof, and/or the driver circuit 500 or a portion thereof. Moreover, the optical system may include one or more lenses, one or more optical elements (e.g., diffractive optical elements, refractive optical elements, or the like), one or more reflector elements, and/or one or more optical sensors, among other examples. In some implementations the optical system may include the optical source.

In some implementations, the driver circuit 200 or a portion thereof, the driver circuit 300 or a portion thereof, the driver circuit 400 or a portion thereof, and/or the driver circuit 500 or a portion thereof may be included in a time-of-flight (ToF)-based (e.g., direct ToF) measurement system. For example, the ToF-based measurement system may include a LIDAR system. According to some implementations, a method may include generating an optical pulse for ToF-based measurement using the driver circuit 200 or a portion thereof, the driver circuit 300 or a portion thereof, the driver circuit 400 or a portion thereof, and/or the driver circuit 500 or a portion thereof; and/or detecting an object based on the optical pulse.

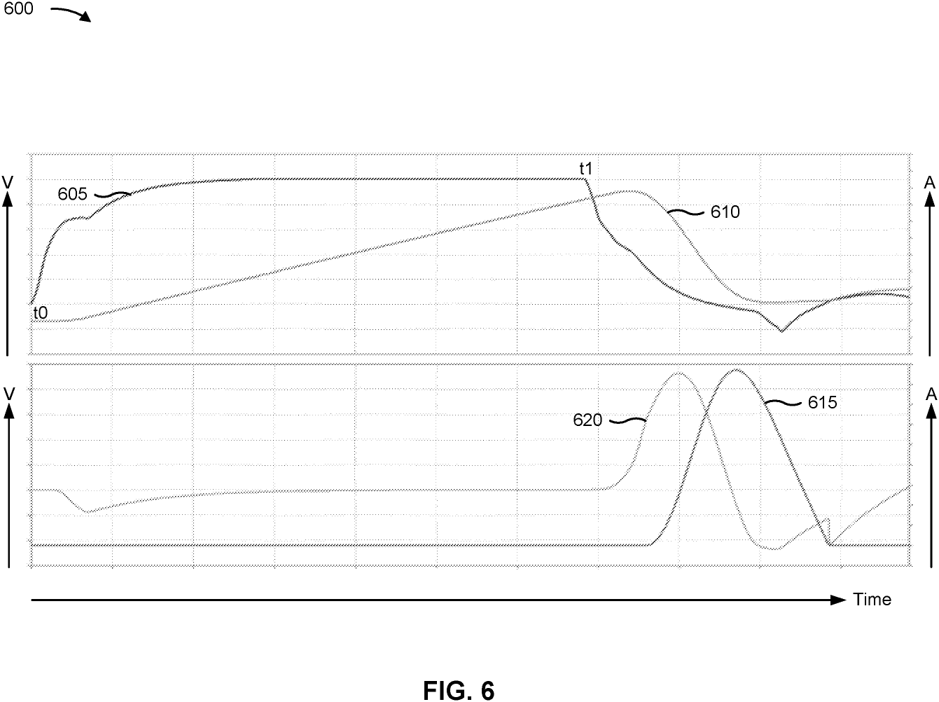

FIG. 6 is a diagram of example graphs 600 plotting electrical signals associated with an example driver circuit described herein. The following description of the graphs 600 is with reference to the driver circuit 200. However, the electrical signals of the graphs 600 may be associated with the driver circuit 200, the driver circuit 300, the driver circuit 400, or the driver circuit 500, described above.

As shown by line 605, during a “charge” signal (e.g., high voltage level) from time t0 to time t1 (e.g., in a range from 1 ns to 20 ns), the switch 220 is in a closed state, causing charging of the inductive element 206. The charging of the inductive element is shown by line 610 (showing current).

As shown by line 615 (showing current), after time t1, the switch 220 is opened and the stored current of the inductive element 206 is discharged through the capacitive element 210 into the optical emitter 208 to provide an optical pulse of the optical emitter 208. Line 620 (showing voltage) shows an output signal, for the signal output 212, at the onset of the rising edge of the electrical pulse caused by discharging the inductive element 206 (shown by line 615). As described herein, the output signal is obtained by diverting a portion of the current from discharging the inductive element 206 to the signal output 212.

As indicated above, FIG. 6 is provided as an example. Other examples may differ from what is described with regard to FIG. 6.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A driver circuit, comprising:
an inductive element;
a first circuit path connected to the inductive element, wherein the first circuit path includes:
an optical emitter; and
a capacitive element in series with the optical emitter;
a second circuit path connected to the inductive element, wherein the second circuit path includes:
a voltage divider element to produce an output signal; and
a signal output configured to provide the output signal to a time-to-digital converter; and
a switch having an open state and a closed state,
wherein the switch in the closed state is to cause current to charge the inductive element, and
wherein the switch transitioning from the closed state to the open state is to cause the inductive element to discharge current to provide an electrical pulse through the first circuit path to the optical emitter and through the second circuit path to the signal output.

2. The driver circuit of claim 1, wherein the capacitive element is between the inductive element and the optical emitter in the first circuit path.

3. The driver circuit of claim 1, wherein the optical emitter is between the inductive element and the capacitive element in the first circuit path.

4. The driver circuit of claim 1, wherein the capacitive element is in the first circuit path and the second circuit path.

5. The driver circuit of claim 1, wherein the optical emitter is in the first circuit path and the second circuit path.

6. The driver circuit of claim 1, wherein the second circuit path branches from the first circuit path between the capacitive element and the optical emitter.

7. The driver circuit of claim 1, further comprising:
an additional capacitive element in the second circuit path.

8. The driver circuit of claim 1, wherein, in response to the electrical pulse, the optical emitter is to emit an optical pulse having a width in a range from 100 picoseconds to 2 nanoseconds.

9. The driver circuit of claim 1, wherein the switch in the closed state is to cause current to charge the inductive element during a time interval in a range from 1 nanosecond to 50 nanoseconds.

10. An optical source, comprising:
a vertical cavity surface emitting laser (VCSEL);
an inductive element;
a first circuit path connected to the inductive element, wherein the first circuit path includes the VCSEL;
a second circuit path connected to the inductive element, wherein the second circuit path includes a signal output; and
a switch having an open state and a closed state,
wherein the switch in the closed state is to cause current to charge the inductive element, and
wherein the switch transitioning from the closed state to the open state is to cause the inductive element to discharge current to provide an electrical pulse through the first circuit path to the VCSEL and through the second circuit path to the signal output.

11. The optical source of claim 10, wherein the inductive element is capacitively coupled to the VCSEL.

12. The optical source of claim 10, wherein the inductive element is capacitively coupled to the signal output.

13. The optical source of claim 10, wherein the second circuit path further includes a voltage divider element to produce an output signal for the signal output.

14. The optical source of claim 10, wherein the second circuit path further includes a transimpedance amplifier to produce an output signal for the signal output.

15. The optical source of claim 10, wherein the second circuit path branches from the first circuit path.

16. The optical source of claim 10, wherein the VCSEL is in the first circuit path and the second circuit path.

17. The optical source of claim 10, wherein the switch is a field effect transistor.

18. A light detection and ranging (LIDAR) system, comprising:
a time-to-digital converter; and
a driver circuit, comprising:
an inductive element;
a first circuit path connected to the inductive element, wherein the first circuit path includes an optical emitter;
a second circuit path connected to the inductive element, wherein the second circuit path includes a signal output configured to provide an output signal to the time-to-digital converter; and
a switch having an open state and a closed state,
wherein the switch in the closed state is to cause current to charge the inductive element, and
wherein the switch transitioning from the closed state to the open state is to cause the inductive element to discharge current to provide an electrical pulse through the first circuit path to the optical emitter and through the second circuit path to the signal output.

19. The LIDAR system of claim 18, wherein the output signal is a start signal for the time-to-digital converter.

20. The LIDAR system of claim 18, wherein the second circuit path branches from the first circuit path.
